(19) United States
(12) Patent Application Publication
(10) Pub. No.: US 2012/0300374 A1
(43) Pub. Date: Nov. 29, 2012

(54) MULTIFUNCTIONAL PERFORMING AND PLAYING DEVICE

(76) Inventors: Yueh-Hua HSU HUANG, New Taipei City (TW); Li-Wei Cho, New Taipei City (TW)

(21) Appl. No.: 13/169,199

(22) Filed: Jun. 27, 2011

(30) Foreign Application Priority Data
May 27, 2011 (TW) 100209491

(51) Int. Cl. H05K 7/00

(52) U.S. Cl. 361/679.01

(57) ABSTRACT

A multifunctional performing and playing device, comprising a holder for a portable electronic device, at least one fastening device and at least one sound playing device, in which the holder can be also used for object placement and the fastening device or the sound playing device is connected to the holder. Furthermore, the sound playing device or the portable electronic device can be directly located on the fastening device as well, thus a performer is allowed to connect the fastening device onto the holder in order to hang the holder on the performer's body, or otherwise the performer can also hang the portable electronic device or the sound playing device on the body simply by using the fastening device. In such a way of versatile combinations, it is possible to, when the performer intends to conduct performances or music playing, distribute the sound generated by the portable electronic device through the sound playing device thereby forming a set of small-scaled multimedia performing and playing apparatus.

### BACKGROUND OF THE INVENTION

1. Field of the Invention

The present invention relates to a multifunctional performing and playing device; in particular, it relates to a multimedia performing and playing device applicable for a portable electronic device.

2. Description of Related Art

Current music performances may involve in using many types of musical instruments like a guitar, an electronic guitar, a bass, an electronic keyboard or a jazz drum set, so performers can thereby demonstrate various styles of fancy or graceful music sounds, presenting unique and fantastic personal charm at performances, thus numerous music fans are attracted to learn to play such musical instruments. However, learning to play musical instruments may be costly and very time consuming, therefore, the passion for learning may probably fade out due to said reasons if the motivation is purely based on personal interests.

On the other hand, the applications of electronic device enabling touch screen controls are presently comprehensive; as a result, certain vendors or manufacturers have developed and presented a lot of music-related application programs (e.g. GarageBand). Taking GarageBand as an example, GarageBand is a professional music software package allowing a performer to use GarageBand as a tool to compose music, play many musical instruments such as piano, guitar, jazz drum set and so forth, which software comprising therein more than 1000 prerecorded sample melodies and more than 50 synthesized musical instrument samples, among other features. Hence, in order to allow convenient utilizations of the software even for a beginner of various musical instruments, it is possible to run the software conjunctively with a touch-screen-based electronic device so that the performer can play a musical instrument directly on the touch screen of the electronic device, thereby preventing the problem concerning purchasing an expensive musical instrument and also facilitating more enjoyable and efficient learning of the musical instrument through the built-in modules of the software.

In this way, with the aid of such useful software, performances of musical instruments may become more adroit and handy; whereas, to conduct performances in public at an open location, it is still required to enlarge the extent of sound propagation, so the externally connected speaker is needed.

Furthermore, to apply the electronic device enabling touch screen control to live performances and hand-carry music compositions would be relatively challenging; without an external stage, such as a table, the performer generally needs to hold the touch-screen-based electronic device with a hand, so it is impossible for the performer to manipulate the software in a versatile fashion by both hands to conduct performances or music compositions. Suppose the movements of the performer become excessively intense and active, the touch-screen-based electronic device may accidentally slide out from the hand of the performer. Therefore, it would be most desirable to find an optimal solution for addressing the issue about carrying the touch-screen-based electronic device along with the conjunctive performance apparatus thereof.

### SUMMARY OF THE INVENTION

One objective of the present invention is to provide a multifunctional performing and playing device which can effectively resolve the issue of carrying the touch-screen-based electronic device along with the conjunctive performance apparatus thereof thereby facilitating more convenient performances of various musical instruments by the performer.

A multifunctional performing and playing device according to the present invention for achieving the aforementioned inventive objective comprises a holder for a portable electronic device, at least one fastening device and at least one sound playing device, in which the holder can be also used for object placement and the fastening device or the sound playing device is located on the holder. Furthermore, the sound playing device or the portable electronic device can be directly located on the fastening device as well, thus a performer is allowed to connect the fastening device to the holder in order to hang the holder on the performer's body, or otherwise the performer can also hang the portable electronic device or the sound playing device on the body simply by using the fastening device. In such a way of versatile combinations, it is possible to, when the performer intends to conduct performances or music playing, distribute the sound generated by the portable electronic device through the sound playing device thereby forming a set of small-scaled multimedia performing and playing apparatus.

More specifically, the portable electronic device comprises a touch screen and the portable electronic device may be a tablet computer or a smartphone.

More specifically, the portable electronic device therein comprises at least one music software.

More specifically, the fastening device includes a fixing part which may be in a form of clasp or an attaching structure thereby that the fastening device can be connected onto the holder or the portable electronic device.

More specifically, the multifunctional performing and playing device can be additionally connected to a battery set which can be located on the holder, the portable electronic device, the fastening device or the sound playing device.

More specifically, the multifunctional performing and playing device can be additionally connected to an amplifier which can be located on the holder, the portable electronic device, the fastening device or the sound playing device.

More specifically, the multifunctional performing and playing device can be additionally connected to a microphone which can be located on the holder, the portable electronic device, the fastening device or the sound playing device.

### BRIEF DESCRIPTION OF THE DRAWINGS

FIG. 1 shows a diagram of stereo structure for a first embodiment of the multifunctional performing and playing device according to the present invention;

FIG. 2 shows a diagram of application for the first embodiment of the multifunctional performing and playing device according to the present invention;

FIG. 3A shows a diagram of additional devices for the first embodiment of the multifunctional performing and playing device according to the present invention;

FIG. 3B shows a diagram of additional devices for the first embodiment of the multifunctional performing and playing device according to the present invention;

FIG. 4 shows a diagram of stereo structure for a second embodiment of the multifunctional performing and playing device according to the present invention;

FIG. 5 shows a diagram of application for the second embodiment of the multifunctional performing and playing device according to the present invention;

FIG. 6A shows a diagram of additional devices for the second embodiment of the multifunctional performing and playing device according to the present invention;

FIG. 6B shows a diagram of additional devices for the second embodiment of the multifunctional performing and playing device according to the present invention;

FIG. 7 shows a diagram of stereo structure for a third embodiment of the multifunctional performing and playing device according to the present invention;

FIG. 8 shows a diagram of application for the third embodiment of the multifunctional performing and playing device according to the present invention;

FIG. 9A shows a diagram of additional devices for the third embodiment of the multifunctional performing and playing device according to the present invention; and

FIG. 9B shows a diagram of additional devices for the third embodiment of the multifunctional performing and playing device according to the present invention.

### DETAILED DESCRIPTION OF THE PREFERRED EMBODIMENTS

The aforementioned and other technical contents, aspects and effects in relation with the present invention can be clearly appreciated through the detailed descriptions concerning the preferred embodiments of the present invention in conjunction with the appended drawings.

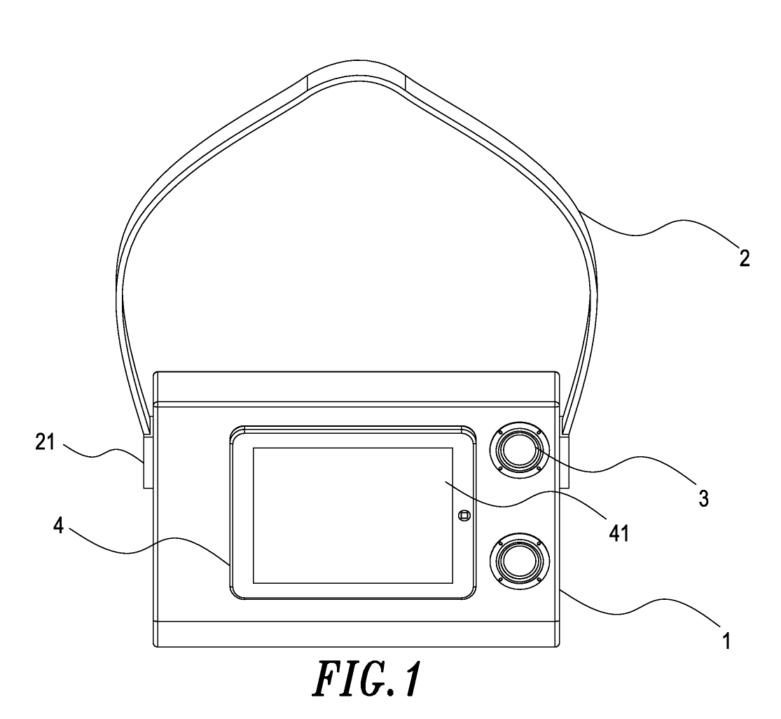

Refer initially to FIGS. 1, 2, 3A and 3B, wherein a diagram of stereo structure, a diagram of application and a diagram of additional devices for a first embodiment of the multifunctional performing and playing device according to the present invention are respectively shown, and it can be seen from such drawings that the illustrated multifunctional performing and playing device comprises:

a holder 1, enabling accommodation of objects and capable of carrying at least one portable electronic device 4;

at least one fastening device 2, connected to the holder 1 in order to hang the holder 1 on the body of a performer 5; and

at least one sound playing device 3, located on the holder 1 and electrically connected to the portable electronic device 4 for playing the sound generated by the portable electronic device 4.

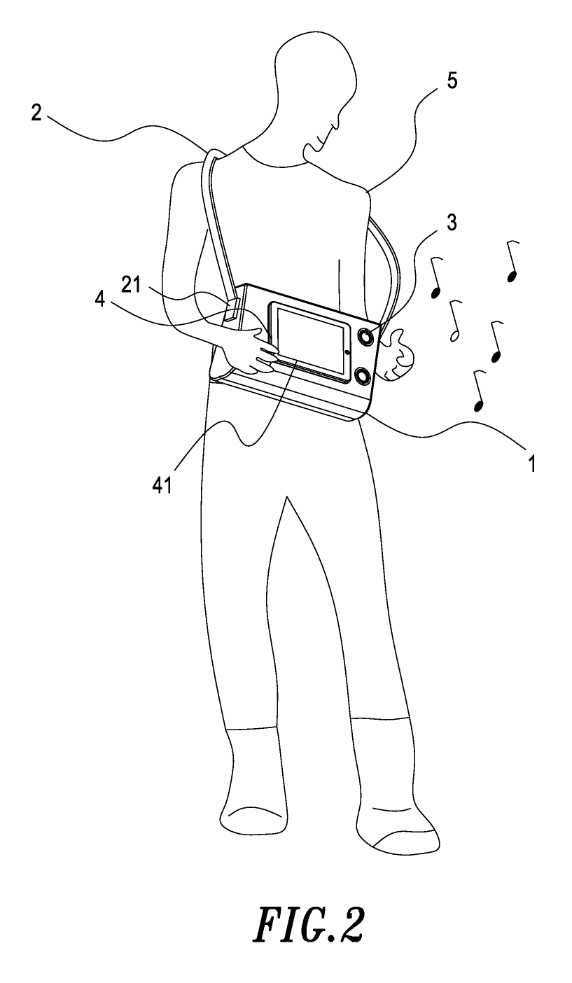

Therefore, as shown in FIG. 2, when the performer 5 hangs the holder 1 on his/her body by means of the fastening device 2, it is possible to directly conduct performances or music playing; besides, in the course of performances or music playing by the performer 5, it is possible to distribute the sound generated by the portable electronic device 4 through the sound playing device 3 thereby forming a set of small-scaled multimedia performing and playing apparatus.

It should be noted that the portable electronic device 4 comprises a touch screen 41 and the portable electronic device 4 may be a tablet computer or a smartphone.

It should be noted that the portable electronic device 4 therein comprises at least one music software.

It should be noted that the fastening device 2 includes a fixing part 21 which may be in a form of clasp or an attaching structure thereby that the fastening device 2 can be connected onto the holder 1 or the portable electronic device 4.

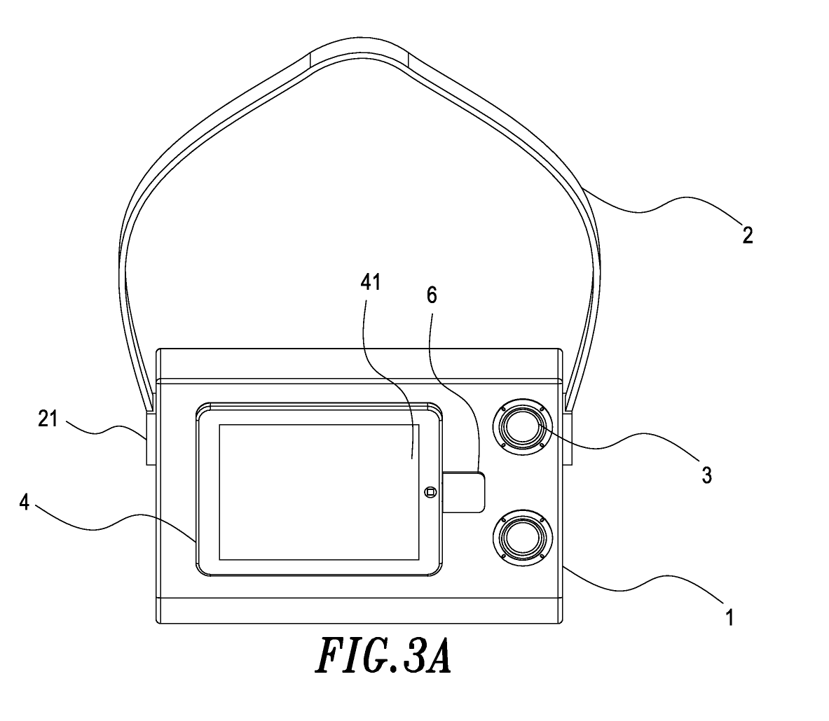

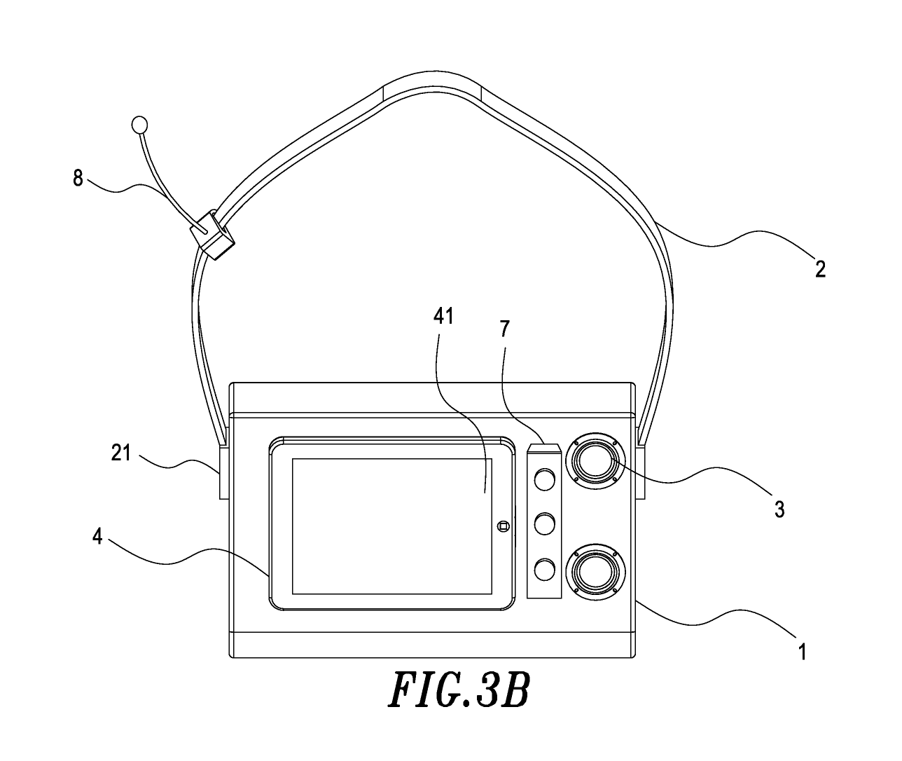

It should be noted that, as shown in FIG. 3A, the multifunctional performing and playing device according to the present invention can be additionally connected to a battery set 6 which can be located on the holder 1 and connected to the portable electronic device 4. Also, optionally, the battery set 6 can be located on the portable electronic device 4, the fastening device 2 or else the sound playing device 3.

It should be noted that, as shown in FIG. 3B, the multifunctional performing and playing device according to the present invention can be additionally connected to an amplifier 7 which can be located on the holder 1 and connected to the portable electronic device 4 as well as the sound playing device 3. Also, optionally, the amplifier 7 can be located on the portable electronic device 4, the fastening device 2 or else the sound playing device 3.

It should be noted that, as shown in FIG. 3B, the multifunctional performing and playing device according to the present invention can be additionally connected to a microphone 8 which can be located on the fastening device 2 and connected to the portable electronic device 4. Also, optionally, the microphone 8 can be located on the holder 1, the portable electronic device 4 or else the sound playing device 3.

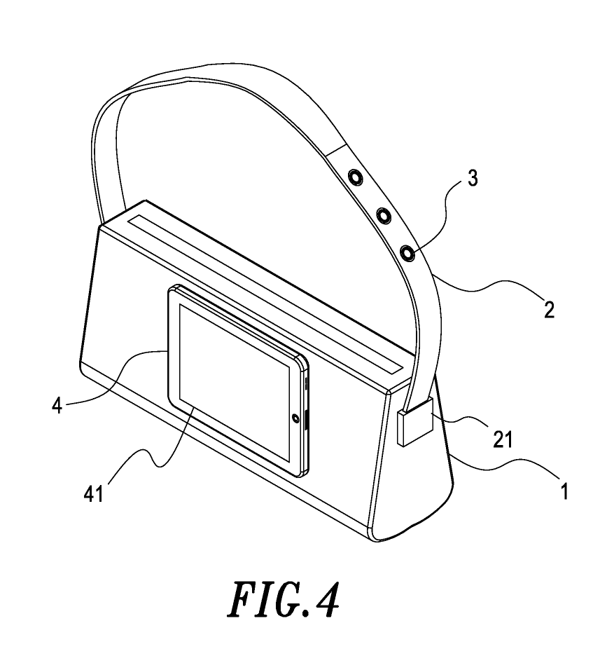

Refer next to FIGS. 4, 5, 6A and 6B, wherein a diagram of stereo structure, a diagram of application and a diagram of additional devices for a second embodiment of the multifunctional performing and playing device according to the present invention are respectively shown, and it can be seen from such drawings that the illustrated multifunctional performing and playing device comprises:

a holder 1, enabling accommodation of objects and capable of carrying at least one portable electronic device 4;

at least one fastening device 2, connected to the holder 1 in order to hang the holder 1 on the body of a performer 5; and

at least one sound playing device 3, located on the fastening device 2 and electrically connected to the portable electronic device 4 for playing the sound generated by the portable electronic device 4.

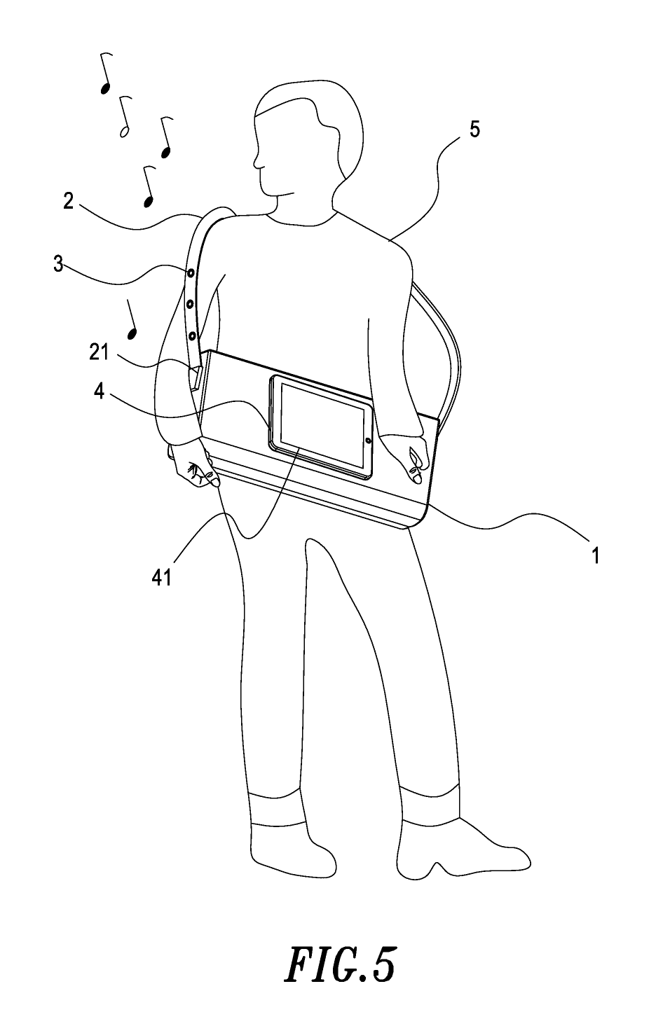

Therefore, as shown in FIG. 5, when the performer 5 hangs the holder 1 on his/her body by means of the fastening device 2, it is possible to directly conduct performances or music playing; besides, in the course of performances or music playing by the performer 5, it is possible to distribute the sound generated by the portable electronic device 4 through the sound playing device 3 thereby forming a set of small-scaled multimedia performing and playing apparatus.

It should be noted that the portable electronic device 4 comprises a touch screen 41 and the portable electronic device 4 may be a tablet computer or a smartphone.

It should be noted that the portable electronic device 4 therein comprises at least one music software.

It should be noted that the fastening device 2 includes a fixing part 21 which may be in a form of clasp or an attaching structure thereby that the fastening device 2 can be connected onto the holder 1 or the portable electronic device 4.

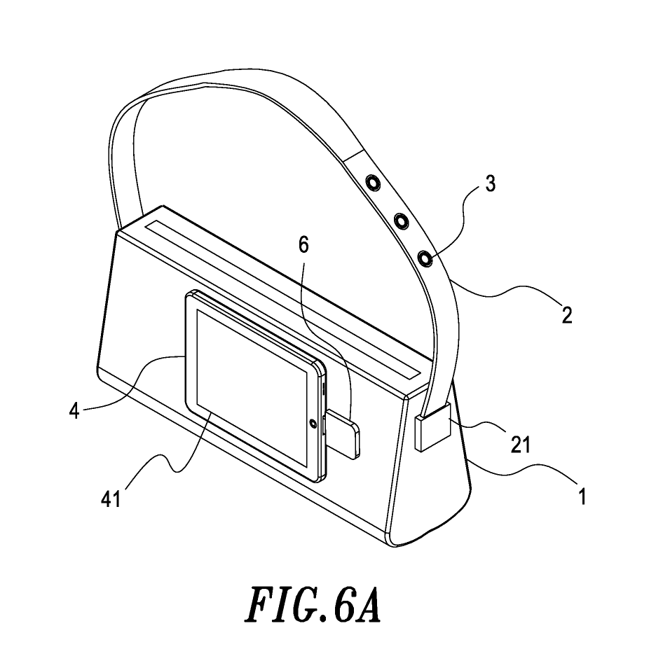

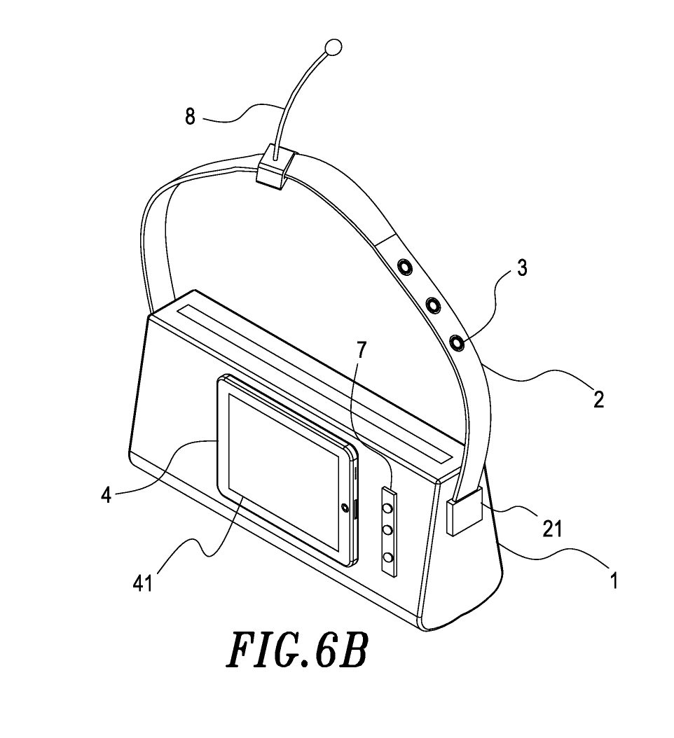

It should be noted that, as shown in FIG. 6A, the multifunctional performing and playing device according to the present invention can be additionally connected to a battery set 6 which can be located on the holder 1 and connected to the portable electronic device 21. Also, optionally, the battery set 6 can be located on the portable electronic device 4, the fastening device 2 or else the sound playing device 3.

It should be noted that, as shown in FIG. 6B, the multifunctional performing and playing device according to the present invention can be additionally connected to an amplifier 7 which can be located on the holder 1 and connected to the portable electronic device 4 as well as the sound playing device 3. Also, optionally, the amplifier 7 can be located on the portable electronic device 4, the fastening device 2 or else the sound playing device 3.

It should be noted that, as shown in FIG. 6B, the multifunctional performing and playing device according to the present invention can be additionally connected to a microphone 8 which can be located on the fastening device 2 and connected to the portable electronic device 4. Also, optionally, the microphone 8 can be located on the holder 1, the portable electronic device 4 or else the sound playing device 3.

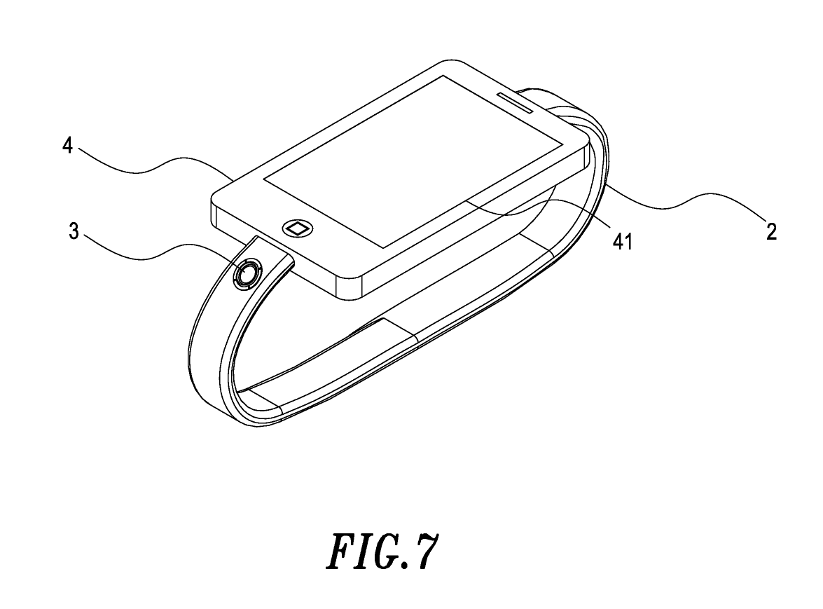

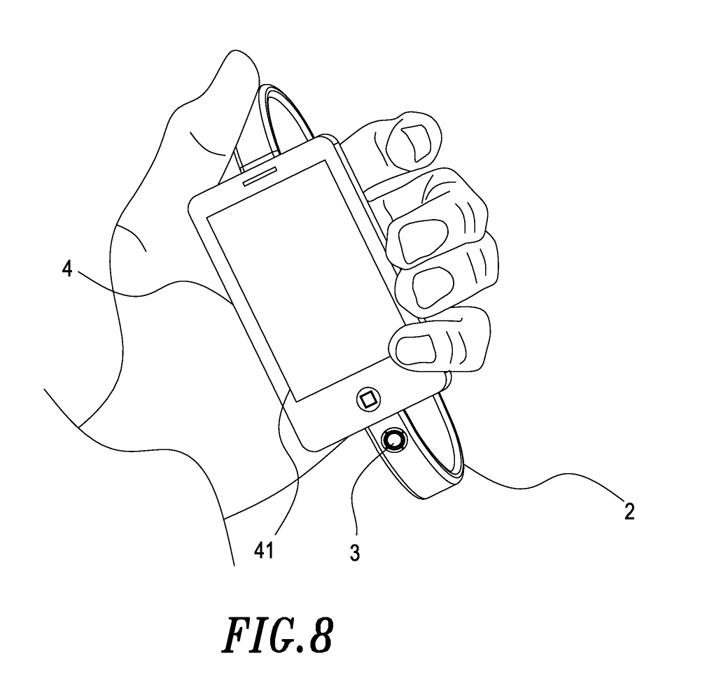

Refer subsequently to FIGS. 7, 8, 9A and 9B, wherein a diagram of stereo structure, a diagram of application and a diagram of additional devices for a third embodiment of the multifunctional performing and playing device according to the present invention are respectively shown. It can be seen from such drawings that the illustrated multifunctional performing and playing device comprises at least one fastening device 2 which is connected to two sides of a portable electronic device 4 in order to hang the portable electronic device 4 on the body of a performer 5 through the fastening device 2. Hence, as shown in FIG. 8, in case that the performer 5 wears the portable electronic device 4 on his/her hand by means of the fastening device 2, it is possible to directly conduct performances or music playing on the hand.

It should be noted that the portable electronic device 4 comprises a touch screen 41 and the portable electronic device 4 may be a tablet computer or a smartphone.

It should be noted that the portable electronic device 4 therein comprises at least one music software.

It should be noted that, as shown in FIG. 7, at least one sound playing device 3 can be connected between the fastening device 2 and the portable electronic device 4, which is electrically connected to the portable electronic device 4 for playing the sound generated by the portable electronic device 4.

It should be noted that the fastening device 2 includes a fixing part (not shown) which may be in a form of clasp or an attaching structure thereby that the fastening device 2 can be connected onto the sound playing device 3 or the portable electronic device 4.

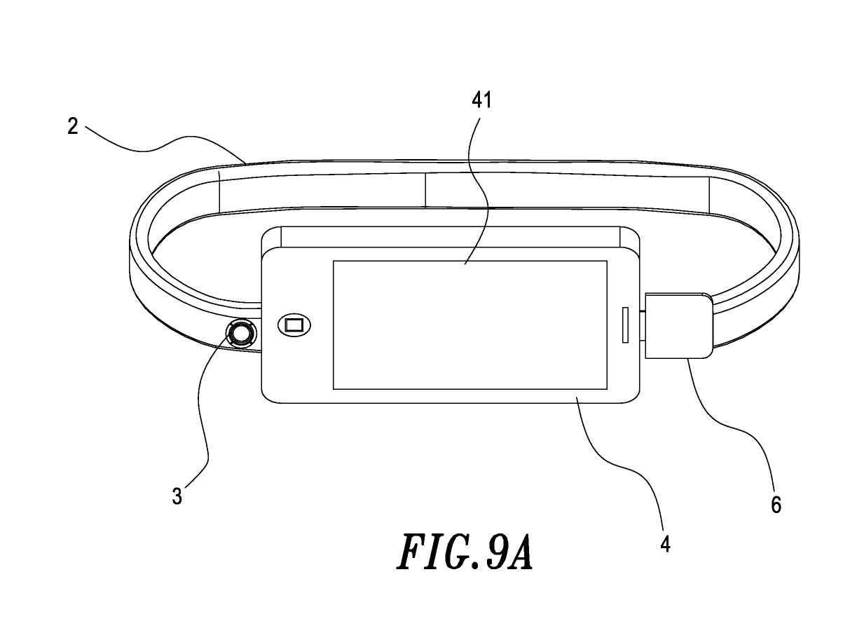

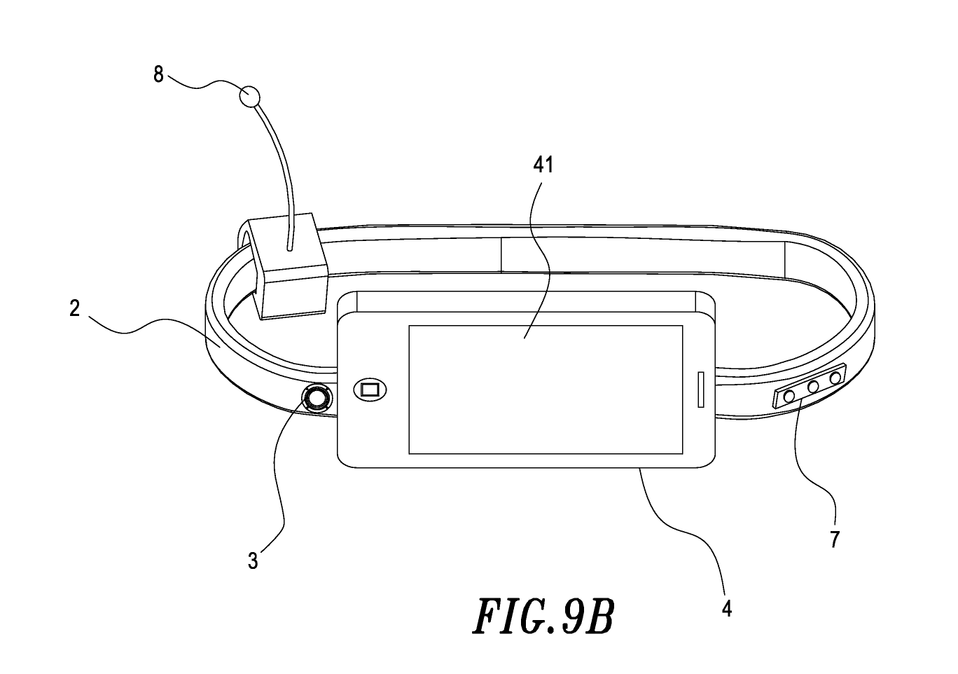

It should be noted that, as shown in FIG. 9A, the multifunctional performing and playing device according to the present invention can be additionally connected to a battery set 6 which can be connected to the portable electronic device 4 and the fastening device 2 and connected to the portable electronic device 4. Also, optionally, the battery set 6 can be located on the portable electronic device 4, the fastening device 2 or else the sound playing device 3.

It should be noted that, as shown in FIG. 9B, the multifunctional performing and playing device according to the present invention can be additionally connected to an amplifier 7 which can be located on the fastening device 2 and connected to the portable electronic device 4 as well as the sound playing device 3. Also, optionally, the amplifier 7 can be located on the portable electronic device 4 or else the sound playing device 3.

It should be noted that, as shown in FIG. 9B, the multifunctional performing and playing device according to the present invention can be additionally connected to a microphone 8 which can be located on the fastening device 2 and connected to the portable electronic device 4. Also, optionally, the microphone 8 can be located on the portable electronic device 4 or else the sound playing device 3.

Compared with other conventional application technologies, the multifunctional performing and playing device provided by the present invention further offers the following advantages:

1. the present invention facilitates convenient utilizations of the touch-screen-based electronic device along with conjunctive performing apparatus thereof, further allowing the performer to conduct performances of various musical instruments in an easier fashion;

2. the present invention allows performers or music composers themselves to determine the disposition of the touch-screen-based electronic device and conjunctive performing apparatus thereof such that performers or music composers can adapt themselves to a more natural and comfortable operation style without holding the touch-screen-based electronic device on the hand.

By way of the aforementioned detailed descriptions for the preferred embodiments according to the present invention, it is intended to better illustrate the characters and spirit of the present invention rather than restricting the scope of the present invention to the preferred embodiments disclosed in the previous texts. Contrarily, the objective is to encompass all changes and effectively equivalent arrangements within the scope of the present invention as delineated in the following claims of the present application.

What is claimed is:

1. A multifunctional performing and playing device, comprising:
a holder, capable of carrying at least one portable electronic device;
at least one fastening device, connected to the holder in order to hang the holder on a user's body; and
at least one sound playing device, located on the holder and electrically connected to the portable electronic device.

2. The multifunctional performing and playing device according to claim 1, wherein the portable electronic device comprises a touch screen.

3. The multifunctional performing and playing device according to claim 2, wherein the portable electronic device is a tablet computer or a smartphone.

4. The multifunctional performing and playing device according to claim 1, wherein the portable electronic device comprises at least one music software.

5. The multifunctional performing and playing device according to claim 1, wherein the fastening device comprises a fixing part and such a fixing part is a clasp or an attaching structure.

6. The multifunctional performing and playing device according to claim 1, wherein a battery set can be additionally connected thereto, which can be located on the holder, the portable electronic device, the fastening device or the sound playing device.

7. The multifunctional performing and playing device according to claim 1, wherein an amplifier can be additionally connected thereto, which can be located on the holder, the portable electronic device, the fastening device or the sound playing device.

8. The multifunctional performing and playing device according to claim 1, wherein a microphone can be additionally connected thereto, which can be located on the holder, the portable electronic device, the fastening device or the sound playing device.

9. A multifunctional performing and playing device, comprising:
a holder, capable of carrying at least one portable electronic device;
at least one fastening device, connected to the holder in order to hang the holder on a user's body; and
at least one sound playing device, located on the holder and electrically connected to the portable electronic device.

10. The multifunctional performing and playing device according to claim 9, wherein the portable electronic device comprises a touch screen.

11. The multifunctional performing and playing device according to claim 10, wherein the portable electronic device is a tablet computer or a smartphone.

12. The multifunctional performing and playing device according to claim 9, wherein the portable electronic device comprises at least one music software.

13. The multifunctional performing and playing device according to claim 9, wherein the fastening device comprises a fixing part and such a fixing part is a clasp or an attaching structure.

14. The multifunctional performing and playing device according to claim 9, wherein a battery set can be additionally connected thereto, which can be located on the holder, the portable electronic device, the fastening device or the sound playing device.

15. The multifunctional performing and playing device according to claim 9, wherein an amplifier can be additionally connected thereto, which can be located on the holder, the portable electronic device, the fastening device or the sound playing device.

16. The multifunctional performing and playing device according to claim 9, wherein a microphone can be additionally connected thereto, which can be located on the holder, the portable electronic device, the fastening device or the sound playing device.

17. A multifunctional performing and playing device, comprising at least one fastening device which is connected to two sides of a portable electronic device in order to hang the portable electronic device on the body of a performer.

18. The multifunctional performing and playing device according to claim 17, wherein the portable electronic device comprises a touch screen.

19. The multifunctional performing and playing device according to claim 18, wherein the portable electronic device is a tablet computer or a smartphone.

20. The multifunctional performing and playing device according to claim 17, wherein the portable electronic device comprises at least one music software.

21. The multifunctional performing and playing device according to claim 17, wherein the fastening device comprises a fixing part and such a fixing part is a clasp or an attaching structure.

22. The multifunctional performing and playing device according to claim 17, wherein at least one sound playing device is connected between the fastening device and the portable electronic device.

23. The multifunctional performing and playing device according to claim 22, wherein a battery set is additionally connected thereto, which can be located on the fastening device, the portable electronic device or the sound playing device.

24. The multifunctional performing and playing device according to claim 22, wherein an amplifier is additionally connected thereto, which can be located on the fastening device, the portable electronic device or the sound playing device.

25. The multifunctional performing and playing device according to claim 22, wherein a microphone is additionally connected thereto, which can be located on the fastening device, the portable electronic device or the sound playing device.
